(19) United States
(12) Patent Application Publication
(10) Pub. No.: US 2026/0266904 A1
(43) Pub. Date: Sep. 10, 2026

(54) MICROCONTROLLER-ASSISTED SELF-TEST FOR PROCESSORS

(71) Applicant: International Business Machines Corporation, Armonk, NY (US)

(72) Inventors: Andrew Singer, Georgetown, TX (US); Drew A. Turner, Underhill, VT (US); Joachim Fenkes, Tübingen (DE); Steven Cano Amaya, Poughkeepsie, NY (US); Timothy Foley, Highland, NY (US)

(21) Appl. No.: 19/075,102

(22) Filed: Mar. 10, 2025

(51) Int. Cl. G01R 31/3187

(52) U.S. Cl. CPC G01R 31/3187

(57) ABSTRACT

A microcontroller assisted self-test includes storing packaged test content on a file system embedded on a chip. A microcontroller embedded on the chip reads the packaged test content. The microcontroller performs a test of an integrated circuit embedded on the chip according to test specification read from the packaged test content. The microcontroller evaluates or determines status of the test and appends the status to a data structure. The microcontroller repeats or iterates through performing of the test, determining and appending of the status until all desired integrated circuits have been tested as specified. The microcontroller communicates the data structure to a device external to the chip.

### BACKGROUND

The present application relates generally to computers, processors, integrated circuit device tests, and more particularly to microcontroller-assisted self-test scheme for processors.

### BRIEF SUMMARY

The summary of the disclosure is given to aid understanding of a system and method that provides a microcontroller-assisted self-test scheme for processors, and not with an intent to limit the disclosure or the invention. It should be understood that various aspects and features of the disclosure may advantageously be used separately in some instances, or in combination with other aspects and features of the disclosure in other instances. Accordingly, variations and modifications may be made to the computer system and/or their method of operation to achieve different effects.

In some embodiments, a computer-implemented method includes storing packaged test content on a file system embedded on a chip. The method also includes reading, by a microcontroller embedded on the chip, the packaged test content. The method also includes performing, by the microcontroller, a test of an integrated circuit embedded on the chip according to test specification read from the packaged test content. The method also includes determining, by the microcontroller, status of the test and appending the status to a data structure. The method also includes repeating the performing of the test, the determining and the appending of the status until all desired integrated circuits have been tested as specified. The method also includes communicating, by the microcontroller, the data structure to a device external to the chip.

In some embodiments, a computer-implemented method includes storing a packaged test content on a file system embedded on a chip. The method also includes reading, by a microcontroller embedded on the chip, the packaged test content. The method also includes performing, by the microcontroller, a test of an integrated circuit embedded on the chip according to a test configuration read from the packaged test content. The method also includes determining, by the microcontroller, fail condition of the test and appending the fail condition to a data structure. The method also includes repeating the performing of the test, the determining and the appending of the fail condition until all desired integrated circuits have been tested as specified. The method also includes communicating, by the microcontroller, the data structure to a device external to the chip.

In some embodiments, a computer program product that includes one or more computer-readable storage media, and program instructions stored on the one or more storage media to perform operations of one or more methods described herein also can be provided.

In some embodiments, computer system is provided that includes a processor set; a set of one or more computer-readable storage media; program instructions, collectively stored in the set of one or more computer-readable storage media, for causing the processor set to perform the computer operations of one or more methods described herein also can be provided.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 shows an example of a computing environment, which can implement microcontroller assisted self-test scheme for processors in some embodiments.

FIG. 2 is a diagram illustrating components and flow involved in testing processors or chips on a die in some embodiments.

FIG. 3 is a diagram showing a parallel configuration of DUTs connected to an ATE in some embodiments.

FIG. 4 is a diagram showing a primary/secondary configuration of DUTs in some embodiments.

FIGS. 5A-5B show a flow diagram illustrating an on-chip self-test method in some embodiments.

FIG. 6 is another flow diagram illustrating a method of microcontroller assisted self-test scheme for processors in some embodiments.

### DETAILED DESCRIPTION

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment ("CPP embodiment" or “CPP”) is a term used in the present disclosure to describe any set of one, or more, storage media (also called "mediums") collectively included in a set of one, or more, storage devices that collectively include machine readable code corresponding to instructions and/or data for performing computer operations specified in a given CPP claim. A "storage device" is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as on-chip microcontroller self-test code 200. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

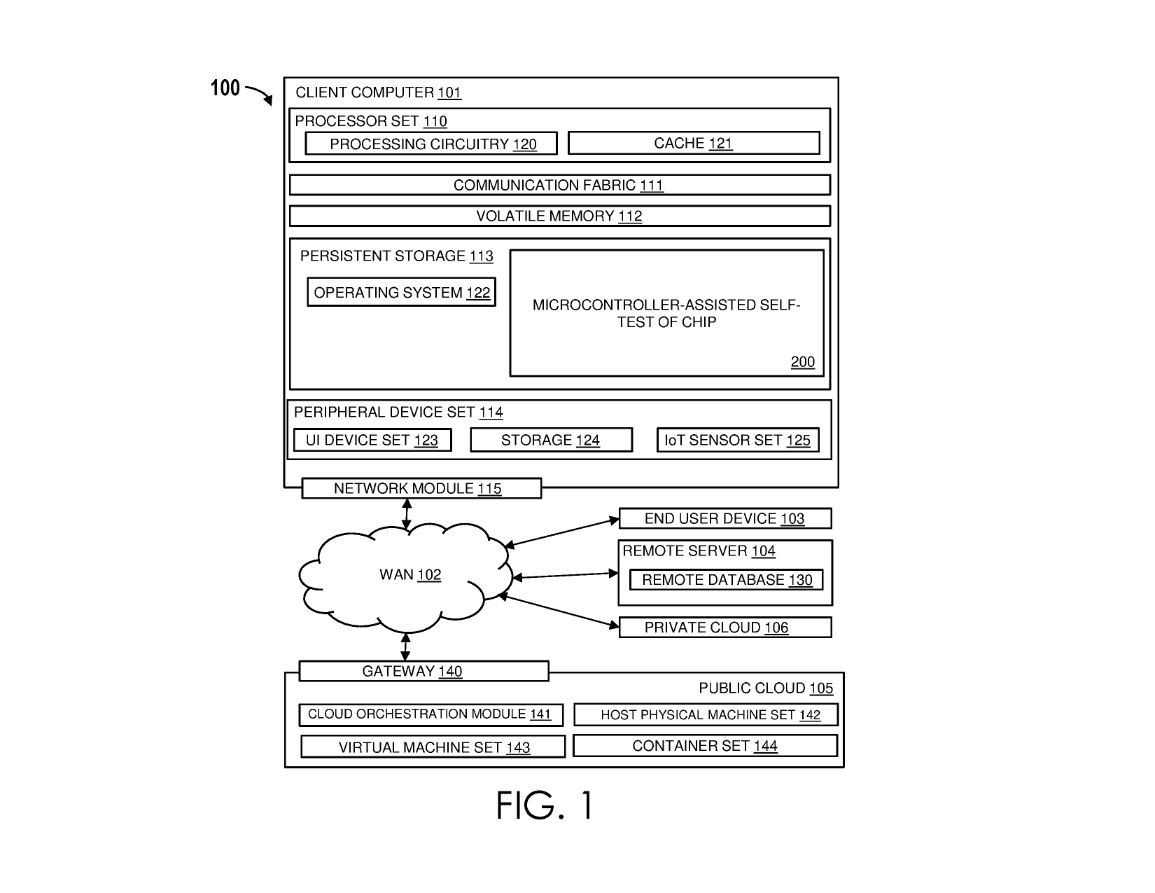

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up buses, bridges, physical input / output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

In some embodiments, systems, methods, and/or techniques are provided that reduce processor design for test complexity (DFT), that is, reduce the amount of physical complexity that is assigned to a processor for the processor to test circuit components on the processor such as a chip. Existing complexity on chip and test logic is shifted to software or firmware. The systems, methods, and/or techniques also increase the processor manufacturing test flexibility, efficiency, and optimization. In some embodiments, a technique disclosed herein shifts test features or complexity into test content packages that can be constructed outside of the chip.

The systems, methods, and /or techniques address the rigidity and growing needs of test specific intellectual property (IP) core insertion, e.g., a technique disclosed herein enables the testing of increasingly complex processors with flexibility and efficiency; effort needed for developing unique test implementation across many products across many sectors, e.g., by allowing minimal duplication of work related to testing products across many sectors; high cost to manage abundance of test instances and test pattern types, costly test time of repeatedly loading abundant data to chip per test instance, and costly test time of unloading all test results from chip to determine pass/fail, e.g., by minimizing repeated loading and unloading of data to and from the chip for each test instance. In some embodiments, the systems, methods, and/or techniques leverage existing on-chip structures such as microcontrollers and file systems, and creates test content packages, to allow the chip to test itself.

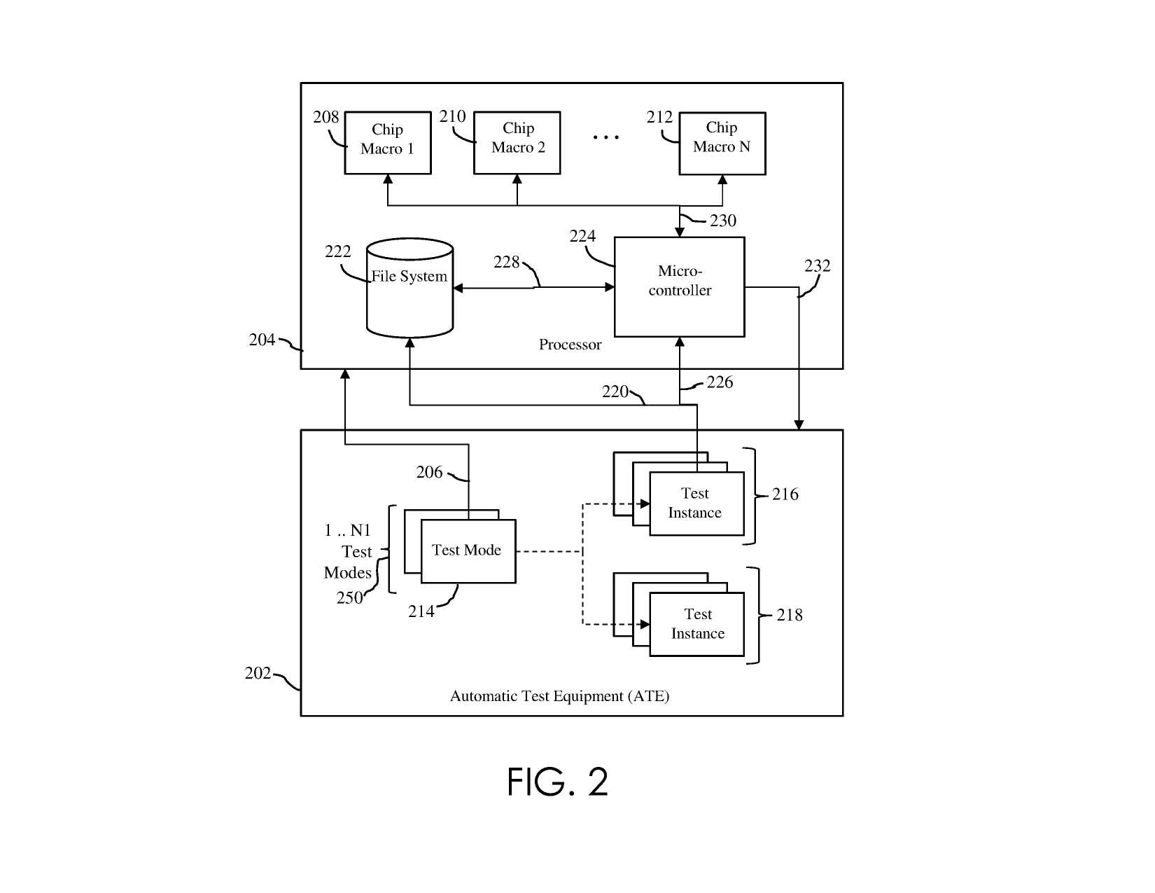

FIG. 2 is a diagram illustrating components and flow involved in testing processors or chips on a die in some embodiments. In some embodiments, an embedded processor test program is provided that enables a processor to perform a self-test on its one or more chips or integrated circuit packages. For instance, once a command to test is received, a chip may perform a test on itself, without needing further interaction with a component that sent the command, the chip providing a status of the performed test upon completion of the test. The status of the test provided by the chip can also be of minimal information, such as “passed” or “failed”. In some embodiments, only failed status may be communicated to minimize further data communication. Minimizing communication or data transmission (loading and unloading of data on and off a chip, reading the data) saves resources such as time, memory consumption, and communication bandwidth.

Shown via a flow at 206, an ATE 202 boots a chip (a packaged integrated circuit), also referred to as a processor 204 to a desired chip mode 214 supporting test instances enabled by desired test content package 216, 218. Automatic test equipment (ATE) is an instrument or device that tests electronic devices, including chips (packaged integrated circuits), for functionality and performance. ATE supports a number of test modes. For example, all supported test modes are shown at 250. The test modes 250 and test instances of test content packages 216, 218 show a hierarchy of conditions to run a single test. For example, there can be N1 total test modes, e.g., shown at 250. A given test mode (e.g., 214) can support N2 total test instances. A test content package may support N3 total test instances, where N3 is a subset of N2. N1, N2, and N3 are integers. For example, a test package is shown at 216. Another example of a test package is shown at 218. Test content package at 216 includes a plurality of test instances. Test content package at 218 includes a plurality of test instances. For example, 216 represents all supported test instances enabled by a test content package; 218 represents all supported test instances enabled by another test content package. In some embodiments, a test instance may be run as many times as specified by the ATE once the supporting test package has been deployed in its supporting test mode. The dotted line connecting 214 with 216 and 218 indicates that 216 and 218 are test content packages supporting a number of test instances which work with a single test mode. For example, test content packages 216, 218 are supported by a given test mode 214. ATE uses hardware and software to send electrical signals to a device, e.g., to test the device, and receives output signals from the device. ATE is capable of automatically testing and diagnosing faults in electronic packaged parts. The processor 204 or chip has one or more chip macros 208, 210, 212. Chip macros 208, 210, 212 can be pre-designed functional blocks of logic within the processor 204 (e.g., within an integrated circuit (IC)) that act as self-contained units.

Shown via a flow at 220, ATE 202 loads compressed content package (e.g., one or more of 216, 218) on on-chip microcontroller file system 222, e.g., a storage or memory location of a microcontroller 224 that is on the processor 204.

Shown via a flow at 226, ATE 202 issues a built-in self test (BIST) test instance command to the microcontroller 224 on the processor 204, also referred to herein as an embedded microcontroller.

Shown via a flow at 228, the microcontroller 224 loads and decompresses test content from the file system 222 on the processor, also referred to as an embedded file system.

Shown via a flow at 230, the microcontroller 224 runs BIST on desired chip macros (e.g., one or more of 208, 210, 212) with settings defined in test package. Also shown via the flow at 230, the microcontroller 224 reads test status, e.g., fail data, from the chip macros (e.g., one or more of 208, 210, 212).

Shown via a flow at 232, the microcontroller 224 returns compressed test summary to ATE 202. In some embodiments, the test summary returned excludes passing data. For instance, only failed data is returned. In this way, time it takes to transfer data is kept at minimum, as well as the amount of data load that is read and communicated, in addition to savings in storage or memory space.

Shown in FIG. 2, by way of example, components that perform flexible on-chip testing includes an automatic tester equipment (ATE) 202, a configurable array of devices-under-test (DUT) 202 (e.g., one DUT is shown), and a microcontroller 224 which is embedded on chip 202, also referred to as an on-chip embedded microcontroller or an embedded microcontroller. Each DUT 202 has a microcontroller 224, enabled to perform microprocessor-assisted (or microcontroller-assisted) self-test (MAT).

In some embodiments, DUTs are configured in parallel. In parallel configuration scenario, the ATE communicates directly to each of the DUTs. In some other embodiments, DUTs are configured in a primary/secondary configuration where communication from the ATE to any variable number of secondaries (secondary DUTs) happens exclusively through the primary.

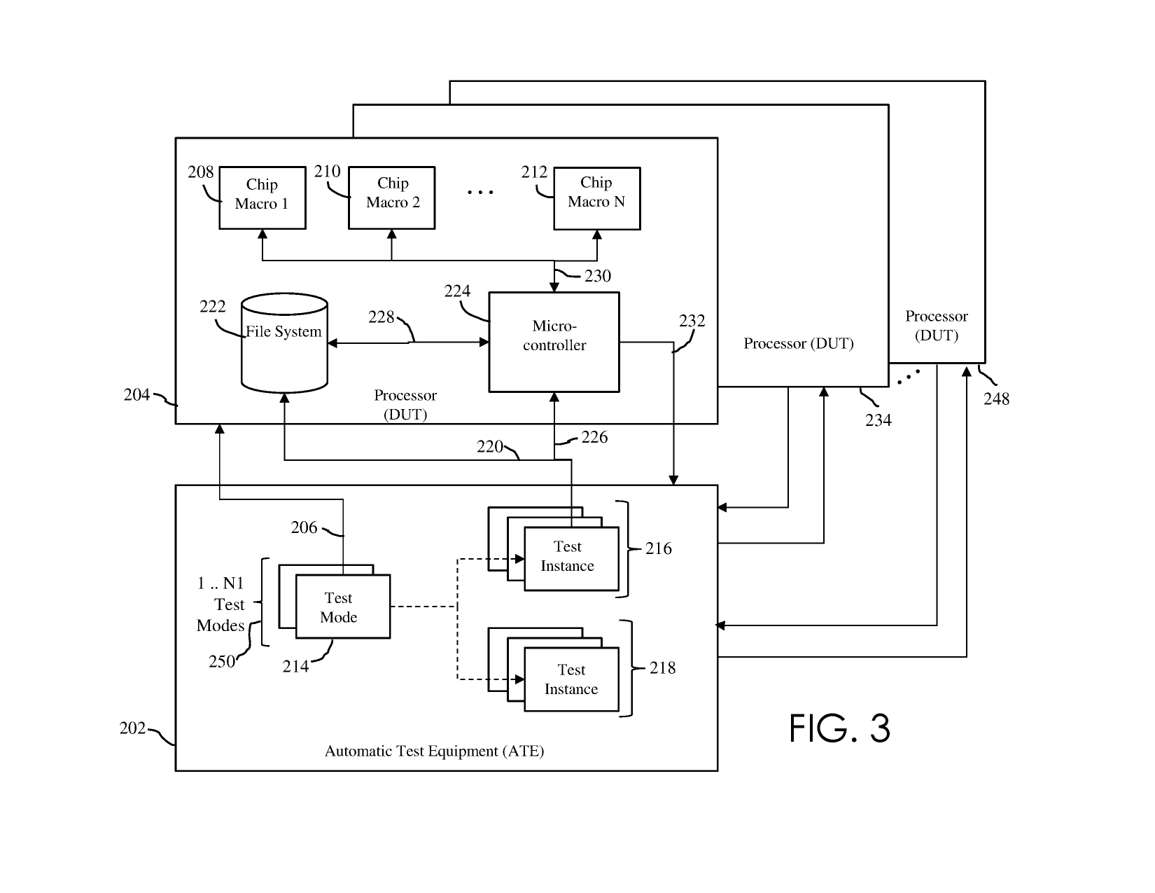

FIG. 3 is a diagram showing a parallel configuration of DUTs connected to an ATE in some embodiments. DUT 204 includes components shown and described with reference to FIG. 2 above. There can be additional DUTs 234, 248, also connected to ATE 202. DUT 234 includes similar components as DUT 204, shown and described with reference to FIG. 2. DUT 248 includes similar components as DUT 204, shown and described with reference to FIG. 2. Each of DUTs 234, 248 communicates with ATE 202 and functions in the same or similar manner as DUT 204 as described above with reference to FIG. 2. For example, ATE 202 communicates directly with each DUTs 204, 236 and 238 in providing test instances and receiving and test results.

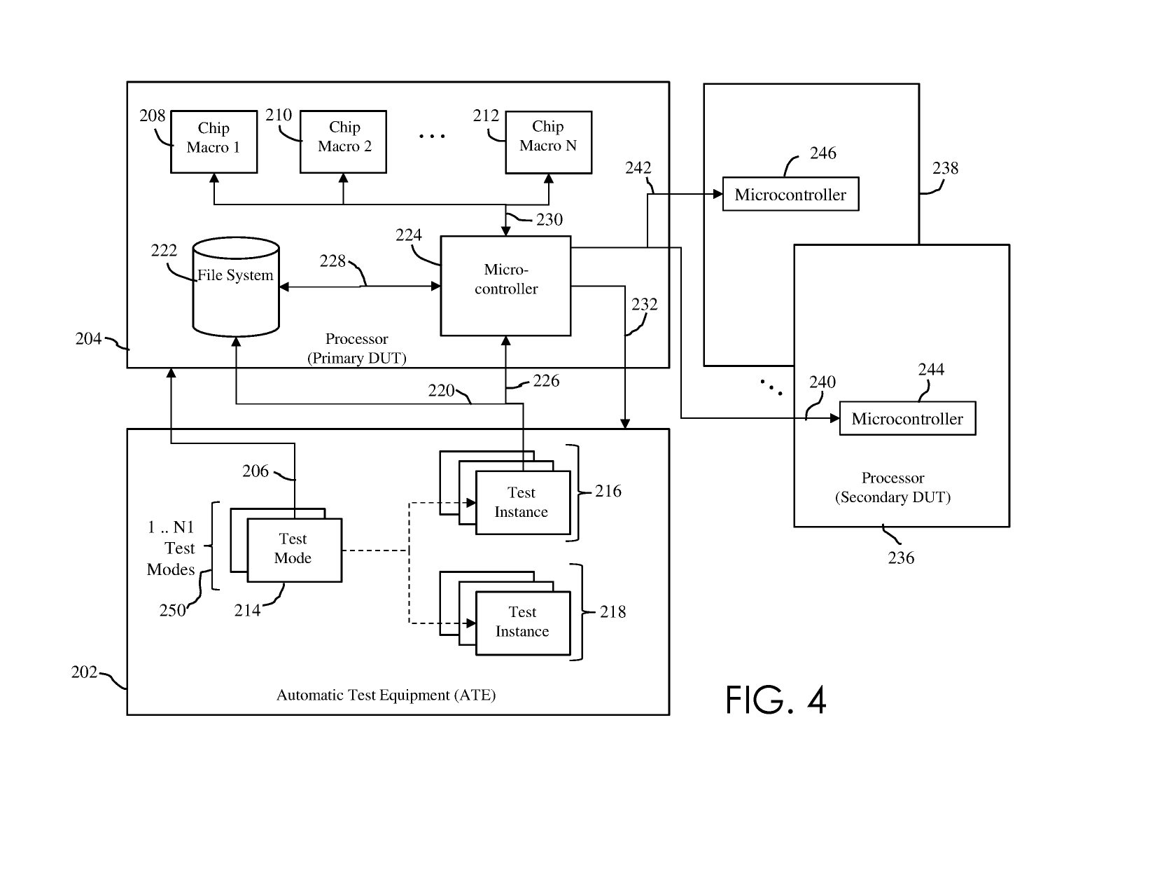

FIG. 4 is a diagram showing a primary/secondary configuration of DUTs in some embodiments. A primary DUT 204 includes components shown and described with reference to FIG. 2 above. There can be one or more secondary DUTs 236, 238. Each of secondary DUTs 236, 238 also includes components shown and described with reference to FIG. 2 above. In the scenario of the primary/secondary configuration, the primary DUT’s microcontroller 232 has a direct communication line to each secondary DUT’s microcontroller (e.g., as shown at 240, 242). Any data sent from the ATE 202 to the primary DUT 204 is distributed sequentially to each secondary DUT’s microcontroller 244, 246 by the primary DUT’s microcontroller 224. This includes test package content that is compiled and compressed prior to execution. In some embodiments, one or more test content packages 216, 218 are supported by a test mode 214. A test content package supports multiple test instances, which allows for test configuration at runtime rather than compile-time. Responsive to receiving content from the primary’s microcontroller 224, each of the secondary DUTs 236, 238 (e.g., their microcontrollers 244, 246) appends test package content to respective secondary DUT’s filesystem in memory for later use during test execution. For example, the secondary DUT’s 236 microcontroller 244 appends test package content to its filesystem in memory for later use during test execution. The ATE 202 can signal to the primary DUT’s microcontroller 224 to begin test execution, which will sequentially communicate to each secondary DUT’s microcontroller 233, 236 to begin the test. Each secondary DUT’s microcontroller 233, 236 uncompresses the package content into heap space on respective each secondary DUT 236, 238 and utilizes the uncompressed package content during the test.

In some embodiments, as execution happens on each DUT 232, 236, 238 in parallel, the primary DUT’s microcontroller 224 “round-robin” polls for pass or fail unload data to be available on each secondary DUT’s communication line, e.g., 240, 242. Pass or fail evaluation happens on-chip on each secondary DUT 236, 238 and fed back to the primary DUT 204 upon completion. For instance, microprocessor 244 on secondary DUT 236 evaluates for pass or fail result or condition of the test and sends the result to the primary DUT 204, e.g., the primary DUT’s microprocessor 224.

In some embodiments, test result data that is communicated, also called unload data, is formatted as Tag-Length-Value (TLV) blocks where each received block has a “tag” with flags indicating the type of data it is, and “length” containing the total byte size of the following variable-length “value” section of the payload. A single secondary DUT can feed back multiple TLV blocks at a time containing scan chain or diagnostics information depending on pass or fail criteria that were met.

In some embodiments, ATE 202 polls the primary DUT 204 waiting for the TLV unload data to be available. Responsive to the primary DUT 204 communicating that data is available to ATE 202, the ATE 202 receives the data (e.g., in double-word increments), and stores the data in ATE capture memory. This process repeats as needed, until the primary DUT 204 signals to the ATE 202 that all data has been transferred.

Upon completion of transfer, ATE 202 retrieves and formats the captured data to be processed and reported based on Tag identity. Upon completion of processing and reporting, ATE 202 signals to begin the next test based on the configuration loaded at runtime

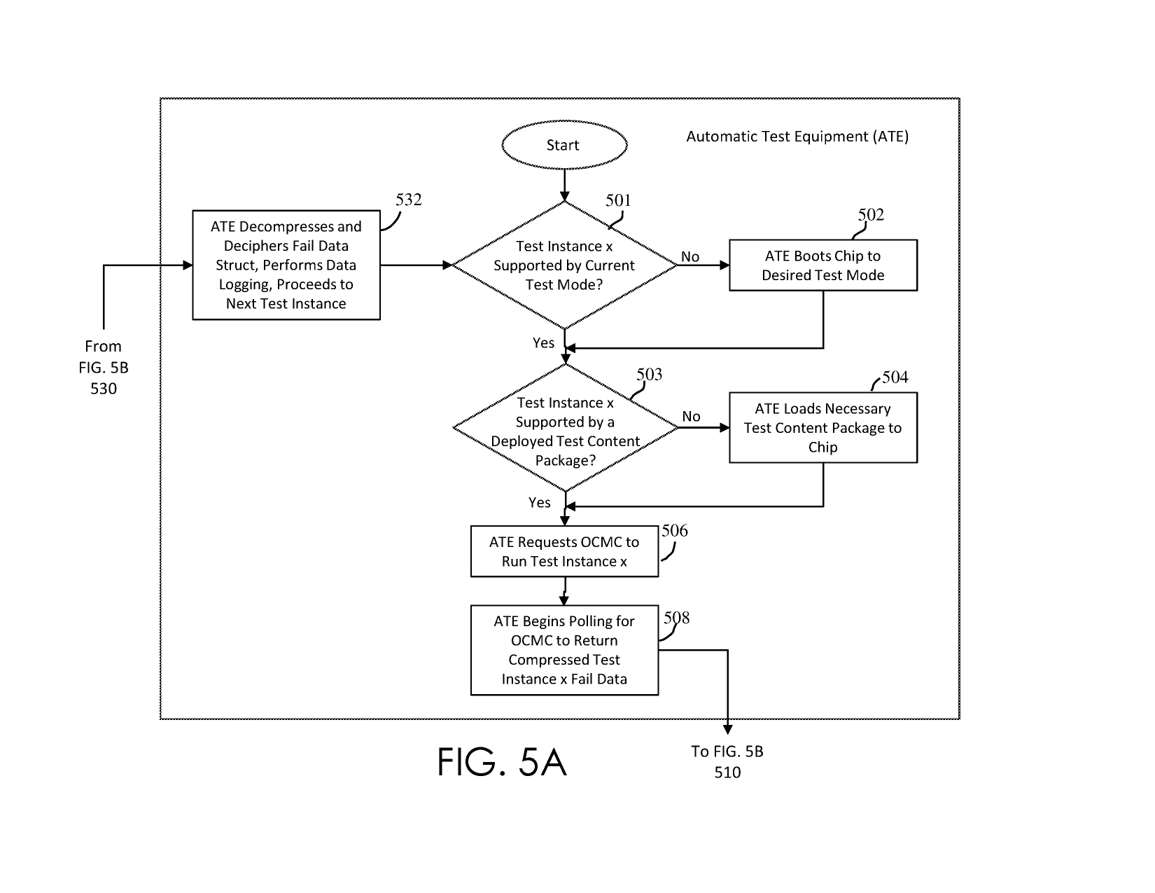

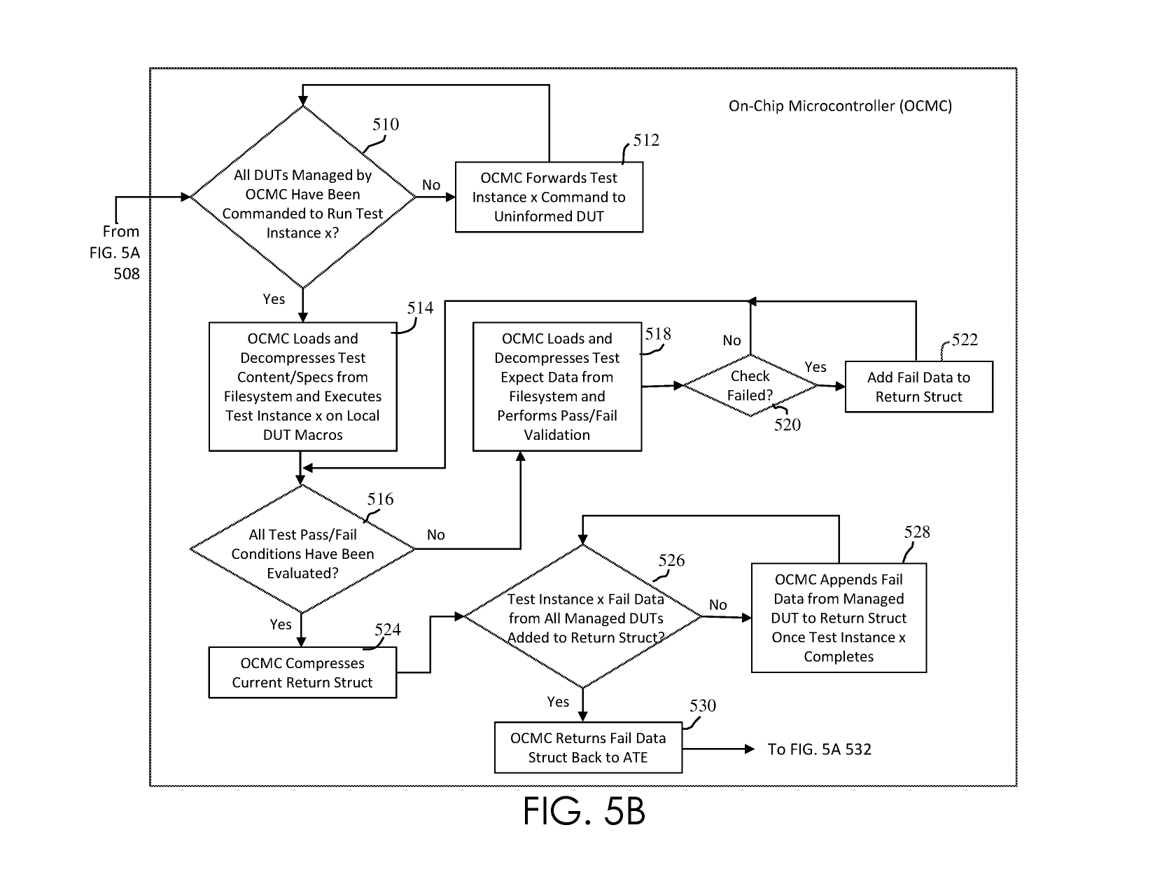

FIGS. 5A-5B show a flow diagram illustrating an on-chip self-test method in some embodiments. At 501, an ATE prepares to execute a test instance (referred to as “test instance x” for simplicity of explanation), and determines whether test instance x is supported by current test mode. For example, the ATE determines whether the chip to test is in test mode that supports test instance x. If the chip is not in the test mode that supports test instance x, at 502, the ATE boots the chip to the desired test mode, i.e., the test mode that supports test instance x. If the chip is in the test mode that supports test instance x, the ATE at 503, determines whether the test content package that supports test instance x is deployed on the chip. As described above, an ATE includes hardware (e.g., a processor such as an integrated circuit) and software which function to perform tests on devices. Test instance x can be specified by a test engineer or the like, who is operating the ATE. Test content or test content package includes, but not limited to, test patterns, settings, images, and/or other information use to run tests. In some embodiments, the test content package also includes expected data, e.g., register values, images of scan chain, which can be used to compare test results to determine pass or fail conditions of a test. Expected data allows the microcontroller to know how to check for fail conditions, for example, check for those conditions and determine whether a fail condition occurred. In some other embodiments, expected data need not be included in the test content package. If the ATE determines that the chip is in the test mode and supports test instance x, the processing proceeds to 506.

At 504, if the chip is not in the test mode, the ATE initializes the chip to the desired test mode. If the chip does not have the test content package for test instance x, the ATE loads compressed test content package to the chip (e.g., the chip’s file system), e.g., during test mode initialization. For example, the ATE causes the chip to initialize to the test mode and loads the content package. The processing proceeds to 506.

At 506, the ATE requests (e.g., sends a signal to) a microcontroller of the chip being tested (on-chip microcontroller, also referred to above as embedded microcontroller) to run test instance x.

At 508, ATE begins polling for the chip’s microcontroller to return test result of the test that the chip performed on itself (also referred to as “self-test”). In some embodiments, the test result that is returned is compressed test instance x fail data.

At 510, the chip’s microcontroller determines whether there are any other DUTs configured in primary/secondary configuration where the current chip is acting as the primary DUT, and if so whether all secondary DUTs have been commanded to run test instance x. If not, at 512, the chip’s microcontroller forwards test instance x command to the secondary DUTs. Once all secondary DUTs, if any, are signaled or commanded to run test instance x, the processing proceeds to 512.

At 514, the chip’s microcontroller loads and decompresses test content and/or test specification from the chip’s file system (e.g., storage or memory buffer) and executes test instance x on local chip (DUT) macros (e.g., shown in FIGS. 2, 3, 4 at 208, 210, 212).

Responsive to executing test instance x on local chip macros (e.g., functional IC blocks or units) on the chip, the chip’s microcontroller evaluates pass or fail test conditions. In some embodiments, evaluating pass or fail test conditions includes loading expected test results (test expect data) from the chips filesystem or storage and performing pass or fail validation by comparing the signals from the chip macros with the test expect data.

If the DUT is configured in primary/secondary configuration, this evaluation and/or validation may be done for all DUTs in that configuration. For example, at 516, the chip’s microcontroller determines whether all test pass or fail conditions have been evaluated. If not, at 518, the chip’s microcontroller loads test expect data from the chips filesystem or storage and performing pass or fail validation by comparing the signals from the chip macros with the test expect data. In some embodiments, loading of test expect data for use in evaluating pass or fail conditions is optional. For example, the microcontroller may evaluate test pass or fail conditions based on other criteria, e.g., the microcontroller can be programmed to read a register and check a bit in the register to validate pass or fail condition.

At 520, the chip’s microcontroller determines whether the check (validation) shows failed condition. If yes, i.e., test resulted in failed condition, at 522, the chip’s microcontroller adds data or information associated with the failed condition to return structure that will be returned to the ATE. As described above, the return structure includes data in TLV format, in some embodiments. Adding only the failed condition to the return structure may minimize the number of bits transferred, and therefore, may decrease overall test time and memory space. Processing proceeds to 516, to repeat checking of all test pass or fail conditions.

Once all test pass or fail conditions have been evaluated, the processing proceeds to 524. At 524, the chip’s microcontroller compresses current return structure.

In the case of primary/secondary configuration scenario, where the current DUT is acting as a primary DUT, at 526, the chip’s microcontroller determines whether there are test instance x fail data from all managed DUTs (secondary DUTs). If not, at 528, the chip’s microcontroller appends fail data from managed DUT to the return structure once test instance x completes on respective managed DUT. Processing at 526 and 528 repeats until test instance x fail data from all managed DUTs have been appended to the return structure.

At 530, the chip’s microcontroller returns fail data structure (appended return structure), back to the ATE.

At 532, the ATE decompresses and deciphers fail data structure. In some embodiments, the ATE also performs any data logging and proceeds to next test instance.

While the techniques described above describe microcontroller-assisted self-test scheme for a processor with an automatic test equipment acting as a host for initiating test mode and loading test content package, then processing the received return data structure containing fail results, other controller or computer may act as the host performing tasks of an ATE described above. For example, another system or an off-the-shelf single board computer can be utilized to initiate self-test of a processor or chip. Such another host may send the test request to an on-chip microcontroller to run a built in self-test, e.g., test instance x, on the chip. That host may also control or configure the type of return data, e.g., full diagnostic data, only failed data, and so forth, allowing for flexible control of the number of bits in the transaction transferred between the host and the microcontroller.

In some embodiments, the host can be the microcontroller on the chip. For example, the functions of the ATE can be migrated to the microcontroller, with the test instance data stored in an auxiliary memory (such as a flash memory) of the chip having the embedded microcontroller.

In some embodiments, systems, methods and techniques provide for manufacturing test maximizing utilization of on-chip pervasive test structures, microcontrollers, and filesystems. In some embodiments, systems, methods and techniques do not require dedicated test access method or dedicated test bus and use the existing system control structures normally used to bootstrap the chip.

In some embodiments, in a self-boot or boot-controller scenario, test flow control is handled by the host or the on-chip microcontroller software. For instance, the host can be an ATE or another computer. As another example, the host can be an on-chip microcontroller. An on-chip microcontroller can perform multiple tests loaded onto its memory buffer, e.g., file system, on its own without intervention from another host such as the ATE.

In some embodiments, the on-chip microcontroller and/or a test equipment such as an ATE use lossless software compression to reduce test data transfer time. In some embodiments, test procedure logic may be migrated from the test program running on the ATE into on-chip microcontrollers, simplifying test pattern logic and enabling a reuse of the test pattern logic across a plurality of test sectors and chip products.

In some embodiments, a microcontroller memory utilizes an embedded filesystem-based approach to allow for flexible and adaptive test content packages.

In some embodiments, test content packages may be used for both production manufacturing test and system field use. In some embodiments, test content packages may be communicated from one tested DUT to another tested DUT for multi-DUT systems. For example, an ATE or like controller equipment may communicate test content packages to multiple DUTs. As another example, a DUT acting as a server or primary can communicate test content packages to another DUT. In some embodiments, test content packages support multiple test instances, each of which implements multiple on-chip test executions.

In some embodiments, an on-chip or embedded microcontroller (e.g., the microcontroller’s software) is responsible for control flow decisions, and level of detail and data type of the return payload. In some embodiments, customized input procedure arguments and decoding of a variable-length output payload happens on the host which may be automatic test equipment, the system, the field, or an off-the-shelf single board computer.

Different configuration points or methods can be implemented for creating or characterizing various test instances and executions per test mode. For example, test instances and executions per test mode can be configured via software hard-coding, software soft-coding, arguments passed to the software, test package contents, and/or using another technique. Hence, different methods can be used to configure how the test is run.

In some embodiments, return data level of detail is optimized by the on-chip microcontroller comparing test results on-chip via the on-chip microprocessor utilizing a mixture of software-based register and scan chain checks, enabling the test equipment to bypass data unload for test results matching expected state or passing state.

In some embodiments, unloaded data is compressed and has variable length, and can exclude expected or passing test results, for optimum test time and on-chip firmware commonality with system. In some embodiments, multiple different modes of data unload scope are supported. For example, return data structure can include full diagnostic unload, fail-only data, or pass/fail summary.

The systems, methods, and techniques reduce processor testing costs and dependencies on external test equipment, enable test development reuse, and further a trend toward on-die test control.

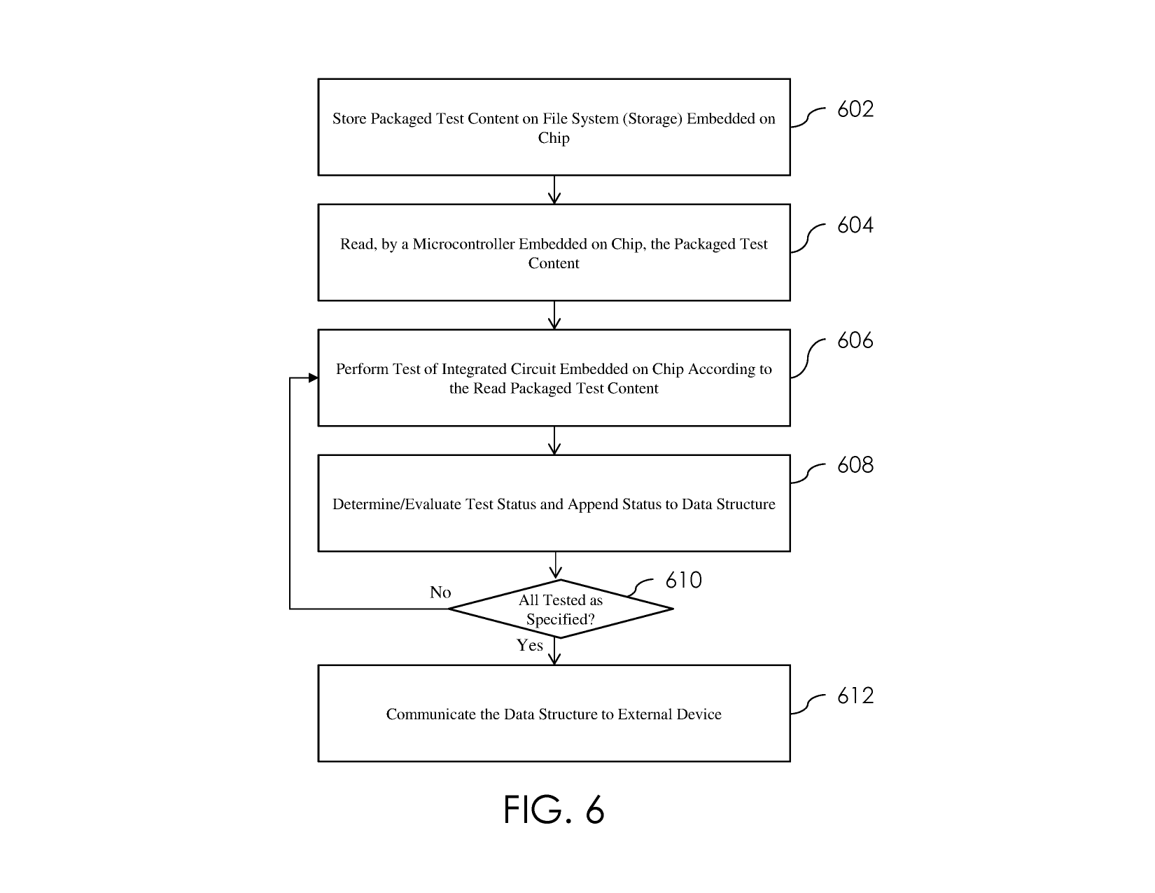

FIG. 6 is another flow diagram illustrating a method of microcontroller assisted self-test scheme for processors in some embodiments. In some embodiments, the method is performed by an on-chip microcontroller or microprocessor. At 602, a microcontroller stores packaged test content on a file system embedded on a chip. For example, as described above, the packaged test content can be received from an external devices such as an ATE. In some embodiments, the packaged test content stored on the file system is a compressed file. In some embodiments, the packaged test content is a lossless compression file. Utilizing compression technique on the packaged test content helps to save storage space of the file system embedded on the chip. In some embodiments, the packaged test content includes multiple test instances that implement multiple on-chip test executions.

At 604, the microcontroller embedded on the chip reads the packaged test content. In some embodiments, the microcontroller further uncompresses the packaged test content, e.g., for reading the content of the packaged test content.

At 606, the microcontroller performs a test of an integrated circuit embedded on the chip according to test specification read from the packaged test content. An integrated circuit embedded on the chip can be IC functional blocks of logic within the chip. By way of example, tests can be performed using on-chip scans and/or clock resources.

At 608, the microcontroller evaluates or determines status of the test and appends the status to a data structure. In some embodiments, the types of the status of the test to be appended to the data structure are configurable via the packaged test content. For example, the packaged test content have specifications as to what types of test data is to be returned, such as the entire diagnostics, only fail conditions, and/or other types of data or payload. For instance, the status of the test that the microcontroller looks for includes fail condition, where only the status that indicates fail condition are appended to the data structure.

The microcontroller repeats the performing of the test, determining and appending of the status until all desired integrated circuits have been tested as specified as shown at 610. In some embodiments, test repetition may be configured at multiple points: E.g., requests by the ATE, on-chip via software control, or specified within the test content package. For example, the method also may include repeating the performing of the test, determining and appending test statuses until testing of all desired integrated circuits and/or managed DUTs as defined by the test instance supported by the test package, the test logic in the microcontroller’s firmware, and/or the test request(s) of the ATE is complete.

At 612, the microcontroller communicates the data structure to a device external to the chip. The device external to the chip can be an ATE. As another example, the device external to the chip can be another processor or computer.

In some embodiments, the microcontroller executes test control software on the microcontroller, where the reading, the performing, the determining and the communicating are performed by the test control software executing on the microcontroller.

In some embodiments, the microcontroller also communicates the packaged test content to another chip, for another chip’s microcontroller to store the packaged test content on said another chip file system, and to perform tests specified in the packaged test content on that another chip. For example, the microcontroller performs those operations as a primary DUT communication with one or more secondary DUTs as described above. In some embodiments, the microcontroller polls for test results from that another chip. In some embodiments, the microcontroller appends the test results from that another chip to the data structure, prior to communicating the data structure to the device external to the chip. In some embodiments, polling for test results from that another chip includes polling for failed condition results from that another chip; and appending the test result from that another chip to the data structure includes appending the failed condition results from that another chip to the data structure.

The terminology used herein is for the purpose of describing particular embodiments only and is not intended to be limiting of the invention. As used herein, the singular forms "a", "an" and "the" are intended to include the plural forms as well, unless the context clearly indicates otherwise. As used herein, the term “or” is an inclusive operator and can mean “and/or”, unless the context explicitly or clearly indicates otherwise. It will be further understood that the terms "comprise", "comprises", "comprising", "include", "includes", "including", and/or "having," when used herein, can specify the presence of stated features, integers, steps, operations, elements, and/or components, but do not preclude the presence or addition of one or more other features, integers, steps, operations, elements, components, and/or groups thereof. As used herein, the phrase “in some embodiments” does not necessarily refer to the same embodiment, although it may. As used herein, the phrase “in one embodiment” does not necessarily refer to the same embodiment, although it may. As used herein, the phrase “in another embodiment” does not necessarily refer to a different embodiment, although it may. Further, embodiments and/or components of embodiments can be freely combined with each other unless they are mutually exclusive.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A computer-implemented method comprising:
storing packaged test content on a file system embedded on a chip;
reading, by a microcontroller embedded on the chip, the packaged test content;
performing, by the microcontroller, a test of an integrated circuit embedded on the chip according to test specification read from the packaged test content;
determining, by the microcontroller, status of the test and appending the status to a data structure;
repeating the performing of the test, determining and appending of the status until all desired integrated circuits have been tested as specified; and
communicating, by the microcontroller, the data structure to a device external to the chip.

2. The computer-implemented method of claim 1, wherein types of the status of the test to be appended to the data structure are configurable via the packaged test content.

3. The computer-implemented method of claim 1, wherein the status of the test includes fail condition, wherein only the status that indicates fail condition is appended to the data structure.

4. The computer-implemented method of claim 1, further including executing test control software on the microcontroller, wherein the reading, the performing, the determining and the communicating are performed by the test control software executing on the microcontroller.

5. The computer-implemented method of claim 1, wherein the packaged test content stored on the file system is a compressed file.

6. The computer-implemented method of claim 1, wherein the packaged test content is a lossless compression file.

7. The computer-implemented method of claim 1, wherein the reading further includes uncompressing the packaged test content.

8. The computer-implemented method of claim 1, further comprising:
communicating the packaged test content to another chip, for another chip’s microcontroller to store the packaged test content on said another chip file system, and to perform tests specified in the packaged test content on said another chip.

9. The computer-implemented method of claim 8, further including:
polling for test results from said another chip; and
appending the test results from said another chip to the data structure, prior to the communicating of the data structure to the device external to the chip.

10. The computer-implemented method of claim 9, wherein the polling for test results from said another chip includes polling for failed condition results from said another chip, and the appending the test result from said another chip to the data structure includes appending the failed condition results from said another chip to the data structure.

11. The computer-implemented method of claim 1, wherein the packaged test content includes multiple test instance that implement multiple on-chip test executions.

12. A computer-implemented method comprising:
storing a packaged test content on a file system embedded on a chip;
reading, by a microcontroller embedded on the chip, the packaged test content;
performing, by the microcontroller, a test of an integrated circuit embedded on the chip according to a test configuration read from the packaged test content;
determining, by the microcontroller, fail condition of the test and appending the fail condition to a data structure;
repeating the performing of the test, determining and appending of the fail condition until all desired integrated circuits have been tested as specified; and
communicating, by the microcontroller, the data structure to a device external to the chip.

13. The computer-implemented method of claim 12, further comprising:
communicating the packaged test content to another chip, for another chip’s microcontroller to store the packaged test content on said another chip file system, and to perform tests specified in the packaged test content on said another chip.

14. The computer-implemented method of claim 13, further including:
polling for fail condition results from said another chip; and
appending the fail condition results from said another chip to the data structure, prior to the communicating of the data structure to the device external to the chip.

15. A computer program product comprising:
one or more computer-readable storage media; and
program instructions stored on the one or more storage media to perform operations comprising:
storing packaged test content on a file system embedded on a chip;
reading, by a microcontroller embedded on the chip, the packaged test content;
performing, by the microcontroller, a test of an integrated circuit embedded on the chip according to test specification read from the packaged test content;
determining, by the microcontroller, status of the test and appending the status to a data structure;
repeating the performing of the test, determining and appending of the status until all desired integrated circuits have been tested as specified; and
communicating, by the microcontroller, the data structure to a device external to the chip.

16. The computer program product of claim 15, wherein types of the status of the test to be appended to the data structure are configurable via the packaged test content.

17. The computer program product of claim 15, wherein the status of the test includes fail condition, wherein only the status that indicates fail condition are appended to the data structure.

18. The computer program product of claim 15, wherein the operations further comprise:
communicating the packaged test content to another chip, for another chip’s microcontroller to store the packaged test content on said another chip file system, and to perform tests specified in the packaged test content on said another chip.

19. The computer program product of claim 18, wherein the operations further comprise:
polling for test results from said another chip; and
appending the test results from said another chip to the data structure, prior to the communicating of the data structure to the device external to the chip.

20. The computer program product of claim 19, wherein the polling for test results from said another chip includes polling for failed condition results from said another chip, and the appending the test result from said another chip to the data structure includes appending the failed condition results from said another chip to the data structure.

21. The computer program product of claim 15, wherein the packaged test content includes multiple test instance that implement multiple on-chip test executions.

22. A computer program product comprising:
one or more computer-readable storage media; and
program instructions stored on the one or more storage media to perform operations comprising:
storing a packaged test content on a file system embedded on a chip;
reading, by a microcontroller embedded on the chip, the packaged test content;
performing, by the microcontroller, a test of an integrated circuit embedded on the chip according to a test configuration read from the packaged test content;
determining, by the microcontroller, fail condition of the test and appending the fail condition to a data structure;
repeating the performing of the test, determining and appending of the fail condition until all desired integrated circuits have been tested as specified; and
communicating, by the microcontroller, the data structure to a device external to the chip.

23. The computer program product of claim 22, wherein the operations further comprise:
communicating the packaged test content to another chip, for another chip’s microcontroller to store the packaged test content on said another chip file system, and to perform tests specified in the packaged test content on said another chip.

24. The computer program product of claim 23, wherein the operations further comprise:
polling for fail condition results from said another chip; and
appending the fail condition results from said another chip to the data structure, prior to the communicating of the data structure to the device external to the chip.

25. A computer system comprising:
a processor set;
a set of one or more computer-readable storage media;
program instructions, collectively stored in the set of one or more computer-readable storage media, for causing the processor set to perform the following computer operations:
storing packaged test content on a file system embedded on a chip;
reading, by a microcontroller embedded on the chip, the packaged test content;
performing, by the microcontroller, a test of an integrated circuit embedded on the chip according to test specification read from the packaged test content;
determining, by the microcontroller, status of the test and appending the status to a data structure;
repeating the performing of the test, determining and appending of the status until all desired integrated circuits have been tested as specified; and
communicating, by the microcontroller, the data structure to a device external to the chip.
